(19) United States
(12) Patent Application Publication
(10) Pub. No.: US 2013/0112249 A1
(43) Pub. Date: May 9, 2013

(54) DYE SENSITIZED SOLAR CELL AND SEALING METHOD THEREOF

(71) Applicant: ELECTRONICS AND TELECOMMUNICATIONS R, Daejeon (KR)

(72) Inventors: Ju Mi KIM, Daejeon (KR); Moo Jung CHU, Daejeon (KR)

(73) Assignee: ELECTRONICS AND TELECOMMUNICATIONS RESEARCH INSTITUTE, Daejeon (KR)

(21) Appl. No.: 13/654,510

(22) Filed: Oct. 18, 2012

(30) Foreign Application Priority Data
Nov. 9, 2011 (KR) 10-2011-0116258

(51) Int. Cl. H01L 51/44; H01L 31/18

(52) U.S. Cl. 136/252; 438/64; 257/E31.117

(57) ABSTRACT

Disclosed are a dye sensitized solar cell and a sealing method thereof. The dye sensitized solar cell includes: an upper electrode glass substrate and a lower electrode glass substrate having a hole formed in at least one thereof; a first sealing material forming a cell internal space by maintaining an interval between the upper electrode glass substrate and the lower electrode glass substrate; an electrolytic solution filled in the cell internal space between the upper electrode glass substrate and the lower electrode glass substrate; and a plug inserted and pressed into the hole to seal the hole.

### CROSS-REFERENCE TO RELATED APPLICATIONS

This application is based on and claims priority from Korean Patent Application No. 10-2011-0116258, filed on Nov. 9, 2011, with the Korean Intellectual Property Office, the disclosure of which is incorporated herein in its entirety by reference.

### TECHNICAL FIELD

The present disclosure relates to a dye sensitized solar cell, and more particularly, to a dye sensitized solar cell and a sealing method thereof capable of easily injecting an electrolytic solution between an upper electrode glass substrate and a lower electrode glass substrate and effectively sealing holes.

### BACKGROUND

Recently, research into the use of natural energy instead of depleting petroleum resources so as to resolve an energy problem has been conducted. In particular, the development of a solar cell using solar energy which is an infinite and environment friendly energy source has been actively conducted.

A silicon solar cell requires a considerable amount of initial facility investment and manufacturing costs and has a limitation in effectively operated areas due to high power generation efficiency only in direct sunlight

A dye sensitized solar cell developed by a team of Michael Gratzel's researchers in 1990s is used in various fields and manufactured at low cost, due to transparent characteristics and as a result, has been in the limelight recently. The dye sensitized solar cell is a photoelectrochemical solar cell that is configured of a photosensitive dye molecule absorbing visible rays to generate an electron-hole pair unlike a P-N junction of the silicon solar cell, a nanoparticle titanium oxide transferring the generated electrons, and an electrolyte assisting a redox of electron.

FIG. 1 is a diagram for describing a manufacturing method of a dye sensitized solar cell according to the related art.

Referring to FIG. 1, the dye sensitized solar cell according to the related art is manufactured by adsorbing a dye 140 to an oxide electrode 130 of an upper electrode glass substrate 110, bonding the upper electrode glass substrate 110 and a lower electrode glass substrate 120, and injecting an electrolytic solution 160. In this case, in order to inject a liquid-state electrolytic solution 160, the upper electrode glass substrate 110 is provided with two holes 112 and 114, wherein the electrolytic solution is injected into one hole 112 and air is absorbed into the other hole 114 so as to minimize bubble formation in a cell.

However, the manufacturing method cannot effectively remove foreign materials adhered around and to an inner wall of the hole 112 after the electrolytic solution 160 is injected and therefore, makes a surface bonding between the inner wall of the hole 112 and a sealing material 170 unstable to leak the electrolytic solution 160 after the predetermined time lapses, which leads to the reduction in lifespan and durability of the solar cell.

In order to resolve the above problems, a method for sealing an electrolytic solution using glass frit which is a similar material to the glass substrate configuring the cell has been used. However, the method needs to locally increase temperature to 600° C. or more so as to melt the glass frit, thereby causing the deformation of the glass substrate and the degradation in performance of the solar cell.

As another manufacturing method, there is a method using a temporary sealing material having viscosity or a plug made of an elastic material so as to seal an electrolytic solution. However, the method also leaks the electrolytic solution after the predetermined time lapses due to the electrolytic solution and impurities adhered to the inner wall of the holes after the electrolytic solution is injected, and requires the high-precision process.

### SUMMARY

The present disclosure has been made in an effort to provide a dye sensitized solar cell and a sealing method thereof capable of effectively cleaning a sealed portion after an electrolytic solution is injected.

The present disclosure also has been made in an effort to provide a dye sensitized solar cell and a sealing method thereof capable of maintaining a long-term sealing state.

An exemplary embodiment of the present disclosure provides a dye sensitized solar cell including: an upper electrode glass substrate and a lower electrode glass substrate having a hole formed in at least one thereof; a first sealing material configured to form a cell internal space by maintaining an interval between the upper electrode glass substrate and the lower electrode glass substrate; an electrolytic solution filled in the cell internal space between the upper electrode glass substrate and the lower electrode glass substrate; and a plug inserted and pressed into the hole to seal the hole.

Another exemplary embodiment of the present disclosure provides a sealing method of a dye sensitized solar cell injected with an electrolytic solution through a hole, the sealing method including: inserting a plug into the hole; and sealing the hole by applying pressure to the plug.

As set forth above, according to the exemplary embodiments of the present disclosure, it is possible to provide the dye sensitized solar cell capable of easily injecting the electrolytic solution at the time of manufacturing the dye sensitized solar cell and improving the sealing performance of the holes to prevent the electrolytic solution from being leaked and improve the durability, by providing the dye sensitized solar cell, which injects the electrolytic solution through the holes formed on the upper electrode glass substrate or the lower electrode glass substrate and inserts and presses the plug having plasticity into the hole to seal the hole, and the sealing method thereof.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram for describing a manufacturing method of a dye sensitized solar cell according to the related art.

FIG. 2 is a cross-sectional view showing a structure of a dye sensitized solar cell according to an exemplary embodiment of the present disclosure.

FIG. 3 is a cross-sectional view showing a structure of a dye sensitized solar cell according to another exemplary embodiment of the present disclosure.

FIGS. 4A and 4B are process flow charts for describing a sealing method of a dye sensitized solar cell according to an exemplary embodiment of the present disclosure.

FIGS. 5A and 5B are process flow charts for describing a sealing method of a dye sensitized solar cell according to another exemplary embodiment of the present disclosure.

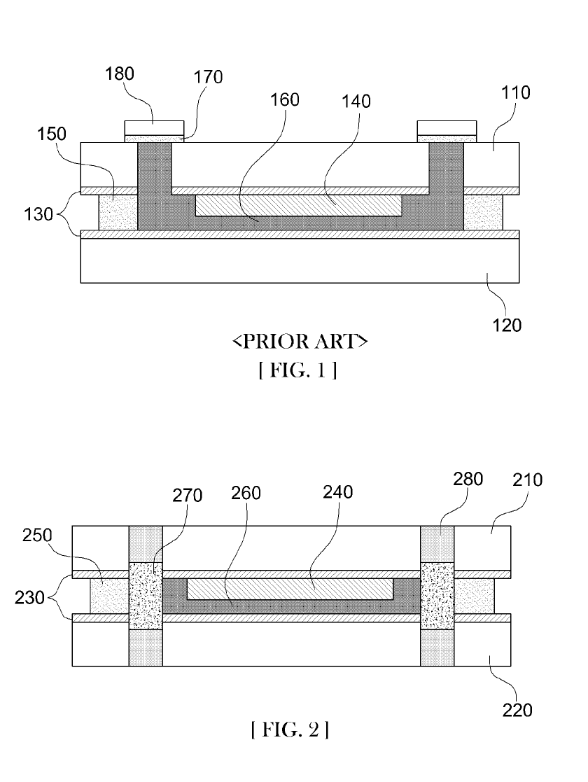

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

A dye sensitized solar cell, which is a cell using a photosynthesis principle of a natural state, uses an electrochemical principle operated through an interface unlike a P-N junction type silicon solar cell in the related art. An operation principle of the dye sensitized solar cell is as follows.

Sunlight is incident through an upper electrode glass substrate and a photonic quantum is absorbed into a dye molecule to excite electrons within a dye molecule. In this case, the electrons of the excited dye molecule are injected into a conduction band of nano oxide semiconductor and move to a lower electrode glass substrate via an external circuit. At the same time, electrons of the oxidized dye are reduced by iodine ions (I−) that are an oxidization-reduction pair within an electrolytic solution and iodine ions (I3−) oxidized within the electrolytic solution are combined with electrons reaching a counter electrode and then, subjected to a reduction reaction, such that the dye sensitized solar cell is operated.

Therefore, it is important to preserve the electrolytic solution within a cell in the dye sensitized solar cell so as to perform the above operation.

Hereinafter, a dye sensitized solar cell and a sealing method thereof for sealing an electrolytic solution in a cell will be described in detail with reference to the accompanying drawings. Further, in describing exemplary embodiments of the present disclosure, well-known functions or constructions will not be described in detail since they may unnecessarily obscure the understanding of the present disclosure.

FIG. 2 is a cross-sectional view showing a structure of a dye sensitized solar cell according to an exemplary embodiment of the present disclosure.

Referring to FIG. 2, a dye sensitized solar cell according to an exemplary embodiment of the present disclosure includes an upper electrode glass substrate 210, a lower electrode glass substrate 220, an oxide electrode 230, a dye 240, a first sealing material 250, an electrolytic solution 260, and a plug 270, and the like.

The upper electrode glass substrate 210 and the lower electrode glass substrate 220 are disposed to face each other, the oxide electrode 230 is formed under the upper electrode glass substrate 210 and over the lower electrode glass substrate 220, and the dye 240 is further formed below the upper electrode glass substrate 210 on which the oxide electrode 230 is formed. In addition, the upper electrode glass substrate 210 and the lower electrode glass substrate 220 according to the exemplary embodiment of the present disclosure are provided with a hole through which the electrolytic solution 260 is injected. In this case, the hole is formed to penetrate through the upper electrode glass substrate 210 and the lower electrode glass substrate 220 in a straight line.

The first sealing material 250 maintains an interval between the upper electrode glass substrate 210 and the lower electrode glass substrate 220 to form a cell internal space.

The electrolytic solution 260 is injected through the hole of the upper electrode glass substrate 210 and the lower electrode glass substrate 220 and is filled in the cell internal space between the upper electrode glass substrate 210 and the lower electrode glass substrate 220.

The plug 270 is inserted and pressed into the hole of the upper electrode glass substrate 210 and the lower electrode glass substrate 220 to seal the hole. To this end, the plug 270 is formed of a material having plasticity, for example, Teflon that is a chemically or mechanically stabilized material or a nonconductor that cannot carry electricity so as to prevent malfunction of a dye sensitized solar cell due to a short circuit of the upper electrode glass substrate 210 and the lower electrode glass substrate 220.

The plug 270 has a diameter smaller than that of the hole before being inserted into the hole of the upper electrode glass substrate 210 and the lower electrode glass substrate 220. This easily discharges an extra electrolytic solution to the outside at the time of press-fitting the plug 270 to minimize the change in internal pressure of the cell, thereby preventing the glass substrates 210 and 220 from being damaged due to a pressure.

The dye sensitized solar cell according to the exemplary embodiment of the present disclosure may further include a second sealing material 280 for secondarily sealing the hole of the upper electrode glass substrate 210 and the lower electrode glass substrate 220. Here, the second sealing material 280 includes a thermoplastic resin or an epoxy resin.

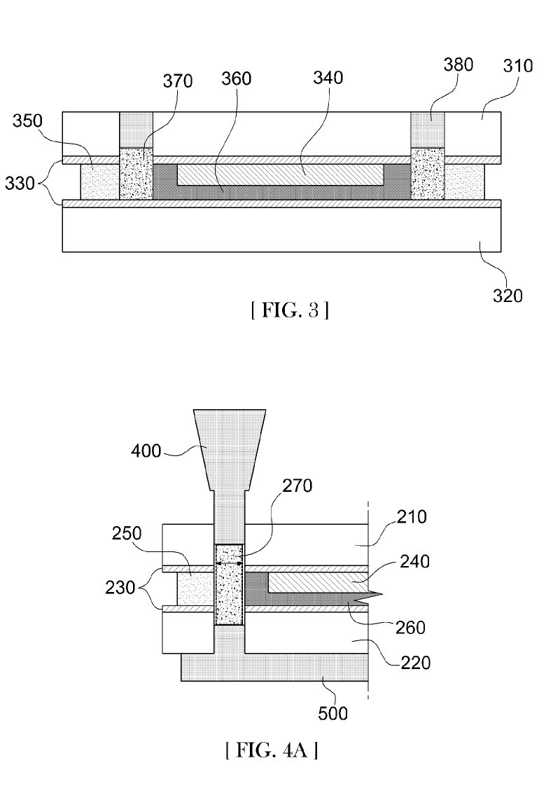

FIG. 3 is a cross-sectional view showing a structure of a dye sensitized solar cell according to another exemplary embodiment of the present disclosure.

Referring to FIG. 3, the dye sensitized solar cell according to another exemplary embodiment of the present disclosure has the same structure as the dye sensitized solar cell of FIG. 2, but has a hole only on the upper electrode glass substrate 310 unlike the dye sensitized solar cell of FIG. 2. Therefore, the dye sensitized solar cell according to another exemplary embodiment of the present disclosure may minimize the process.

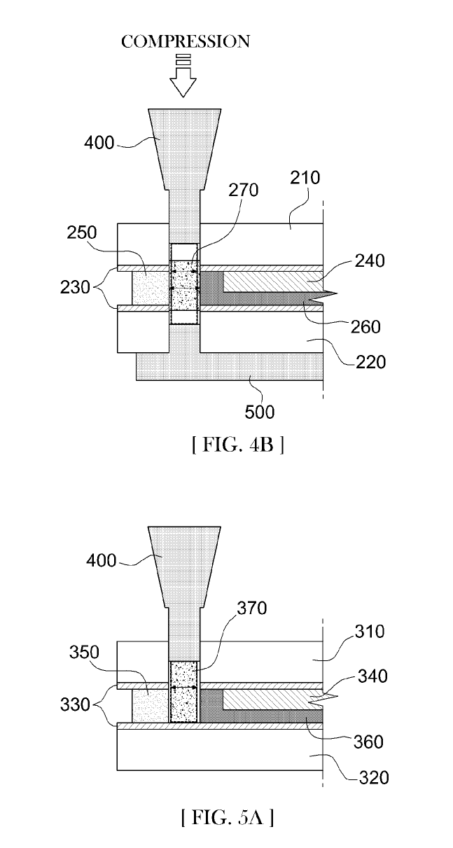

FIGS. 4A and 4B are process flow charts for describing a sealing method of a dye sensitized solar cell according to an exemplary embodiment of the present disclosure.

As shown in FIG. 4A, the plug 270 is inserted into the hole of the upper electrode glass substrate 210 and the lower electrode glass substrate 220.

Thereafter, as shown in FIG. 4B, the plug 270 is vertically pressed by a lower press pin 500 and an upper press 400 to be compressed and deformed, thereby sealing the inside of the hole.

Although not shown, the sealing performance of the dye sensitized solar cell can be improved by cleaning the electrolytic solution or impurities adhered to the hole surface and the inner wall of the upper electrode glass substrate 210 and the lower electrode glass substrate 220 and secondarily sealing the hole using sealing material 280.

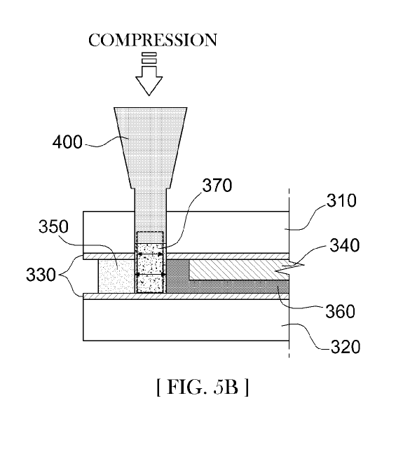

FIGS. 5A and 5B are process flow charts for describing a sealing method of a dye sensitized solar cell according to another exemplary embodiment of the present disclosure.

As shown in FIG. 5A, a plug 370 is inserted into the hole of the upper electrode glass substrate 310 and the lower electrode glass substrate 320.

Thereafter, as shown in FIG. 5B, the plug 370 is pressed downwardly by the upper press 400 to be compressed and deformed, thereby sealing the inside of the hole. In this case, since the lower electrode glass substrate 320 substitutes for a role of the lower press pin 500 of FIG. 4A, another exemplary embodiment of the present disclosure does not require the lower press pin 500.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A dye sensitized solar cell, comprising:
an upper electrode glass substrate and a lower electrode glass substrate having a hole formed in at least one thereof;
a first sealing material configured to form a cell internal space by maintaining an interval between the upper electrode glass substrate and the lower electrode glass substrate;
an electrolytic solution filled in the cell internal space between the upper electrode glass substrate and the lower electrode glass substrate; and
a plug inserted and pressed into the hole to seal the hole.

2. The dye sensitized solar cell of claim 1, wherein: the plug is formed of a material having plasticity.

3. The dye sensitized solar cell of claim 1, wherein: the plug is a nonconductor.

4. The dye sensitized solar cell of claim 1, wherein: the plug has a diameter smaller than that of the hole before being inserted into the hole.

5. The dye sensitized solar cell of claim 1, wherein: when the hole is formed on both of the upper electrode glass substrate and the lower electrode glass substrate, the hole is formed to penetrate through the upper electrode glass substrate and the lower electrode glass substrate in a straight line.

6. The dye sensitized solar cell of claim 1, further comprising:
a second sealing material configured to secondarily seal the hole.

7. The dye sensitized solar cell of claim 6, wherein: the second sealing material includes a thermoplastic resin or an epoxy resin.

8. A sealing method of a dye sensitized solar cell injected with an electrolytic solution through a hole, comprising:
inserting a plug into the hole; and
sealing the hole by applying pressure to the plug.

9. The sealing method of claim 8, further comprising:
cleaning a surface and an inner wall of the hole; and
secondarily sealing the hole using a sealing material.

10. The sealing method of claim 9, wherein in the sealing of the hole, the hole is sealed by vertically applying pressure toward an upper portion or a lower portion of the plug.
